(19) United States
(12) Patent Application Publication
(10) Pub. No.: US 2007/0111449 A1
(43) Pub. Date: May 17, 2007

(54) Non-volatile memory cell and method for manufacturing the same

(76) Inventors: Hsu-Sheng Yu, Hsinchu (TW); Chun-Hung Lee, Hsinchu (TW)

Correspondence Address: J.C. Patents, Inc., Suite 250, 4 Venture, Irvine, CA, 92618, US

(21) Appl. No.: 11/281,272

(22) Filed: Nov. 16, 2005

(51) Int. Cl. H01L 21/336

(52) U.S. Cl. 438/264

(57) ABSTRACT

The invention is directed to a method for manufacturing a non-volatile memory. The method comprises steps of forming a stacked gate structure over a substrate, wherein the stacked gate structure is composed of, from the bottom to the top of the stacked gate structure, a first dielectric layer, a charge storage layer, a second dielectric layer, a conductive layer and a cap layer. A source/drain region is formed in the substrate. A protective layer is formed on the sidewall of the stacked gate structure. An etching process is performed to remove the cap layer, wherein, in the etching process, the cap layer and the protective layer have different etching rate.

### BACKGROUND OF THE INVENTION

1. Field of Invention

The present invention relates to a memory device and a method for manufacturing the same. More particularly, the present invention relates to a non-volatile memory cell having a protection for a gate dielectric layer in the stacked gate structure and a method for manufacturing the same.

2. Description of Related Art

The non-volatile memory possesses the advantages such as small volume, fast accessing speed and low power consumption. Therefore, the non-volatile memory is widely used in the mass storage device of the portable handy terminal such as digital still cameras and memory cards.

The non-volatile memory is composed of several memory cell which are arranged in a form of array. The stacked gate structure of the typical memory cell comprises a control gate, a gate dielectric layer, a floating gat and a tunnel oxide layer. The method for forming the stacked gate structure comprises steps of depositing the material layers and etching the material layers by using a single photoresist layer as a mask. However, the thickness of the photoresist layer should be thick enough to resist against erosion of the etching process. With the decrease of the size of the device, the depth of focus (DOF) is getting small. The thicker the photoresist layer is, the more difficult the photolithography can be performed. Therefore, it is necessary to fine a proper way to manufacture the stacked gate structure of the memory cell.

### SUMMARY OF THE INVENTION

Accordingly, at least one objective of the present invention is to provide a method for manufacturing a non-volatile memory. By using the method of the present invention, the gate structure of the memory cell can be well defined even the focusing depth is limited.

To achieve these and other advantages and in accordance with the purpose of the invention, as embodied and broadly described herein, the invention provides a method for manufacturing a non-volatile memory. The method comprises steps of forming a stacked gate structure over a substrate, wherein the stacked gate structure is composed of, from the bottom to the top of the stacked gate structure, a first dielectric layer, a charge storage layer, a second dielectric layer, a conductive layer and a cap layer. A source/drain region is formed in the substrate. A protective layer is formed on the sidewall of the stacked gate structure. An etching process is performed to remove the cap layer, wherein, in the etching process, the cap layer and the protective layer have different etching rate.

In aforementioned embodiment of the present invention, the thickness of the protective layer is about 50˜200 angstrom.

In aforementioned embodiment of the present invention, the method for forming the protective layer comprises steps of forming a conformal protective layer over the substrate and removing a portion of the conformal protective layer to form the protective layer on the sidewall of the stacked gate structure.

In aforementioned embodiment of the present invention, the material of the protective layer is different from that of the cap layer.

In aforementioned embodiment of the present invention, when the cap layer is made of silicon oxide, the protective layer is made of silicon nitride.

In aforementioned embodiment of the present invention, when the cap layer is made of silicon oxide and the protective layer is made of silicon nitride, the method for removing the portion of the conformal protective layer includes a dry etching process and a recipe of the dry etching process comprises the flow rate of CHF₃ of about 40 sccm˜60 sccm and the oxygen flow rate of about 200 sccm˜400 sccm.

In aforementioned embodiment of the present invention, when the material of the protective layer is silicon oxide, the material of the cap layer is silicon nitride.

In aforementioned embodiment of the present invention, when the material of the protective layer is silicon oxide and the material of the cap layer is silicon nitride, the method for removing the portion of the conformal protective layer includes a dry etching process and a recipe of the dry etching process comprises the flow rate of C₄F₆ of about 5 sccm˜15 sccm and the oxygen flow rate of about 5 sccm˜15 sccm.

In aforementioned embodiment of the present invention, the method for forming the stacked gate structure comprises steps of forming a first dielectric material layer, a charge storage material layer, a second dielectric material layer, a conductive material layer and a cap material layer sequentially and forming a patterned photoresist layer over the cap material layer. The cap material layer is etched by using the patterned photoresist layer as a mask to form the cap layer and the patterned photoresist layer is removed. The conductive material layer, the second dielectric material layer, the charge storage material layer and the first dielectric material layer are etched by using the cap layer as a mask to form the stacked gate structure.

In aforementioned embodiment of the present invention, the etching process includes a wet etching process.

In aforementioned embodiment of the present invention, after the cap layer is removed, a self-aligned metal silylation process is performed to from a metal silicide layer over the stacked gate structure.

In aforementioned embodiment of the present invention, after the cap layer is removed and before the self-aligned metal silylation process is performed, a spacer is formed on the protective layer over the sidewall of the stacked gate structure.

The present invention also provides a non-volatile memory cell. The non-volatile memory cell comprises a substrate, a stacked gate structure, a protective layer and several doped regions. The stacked gate structure is located on the substrate, wherein the stacked gate structure is composed of, from the bottom to the top of the stacked gate structure, a first dielectric layer, a charge storage layer, a second dielectric layer, a conductive layer and a cap layer. The protective layer is located on the sidewall of the stacked gate structure and the doped regions are located in the substrate adjacent to both sides of the stacked gate structure.

In aforementioned embodiment of the present invention, the thickness of the protective layer is about 50˜200 angstrom.

In aforementioned embodiment of the present invention, the material of the protective layer is silicon oxide.

In aforementioned embodiment of the present invention, the material of the cap layer is silicon nitride.

In aforementioned embodiment of the present invention, it further comprises a metal silicide layer located on the stacked gate structure.

In aforementioned embodiment of the present invention, it further comprises a spacer located on the protective layer over the sidewall of the stacked gate structure.

In the present invention, since the photoresist layer is used as a mask for patterning the cap layer and then the patterned cap layer is used as a hard mask for patterning the material layers in the stacked gate structure, the thickness of the photoresist layer can be relatively small. Furthermore, because the protective layer is located on the sidewall of the stacked gate structure, the material layers in the stacked gate structure can be prevented from being damaged in the etching process. Therefore, the electrical performance of the memory cells is uniform.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1G are cross-sectional views showing a method for manufacturing a non-volatile memory cell according to a preferred embodiment of the invention.

FIG. 2 is a top view of FIG. 1G, wherein FIG. 1G is the cross-sectional view along a line I-I′ on FIG. 2.

### DESCRIPTION OF THE PREFERRED EMBODIMENTS

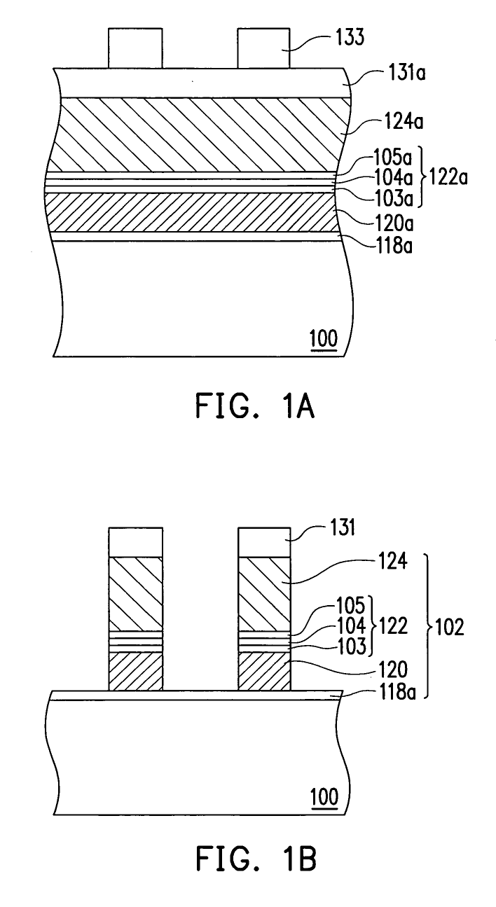

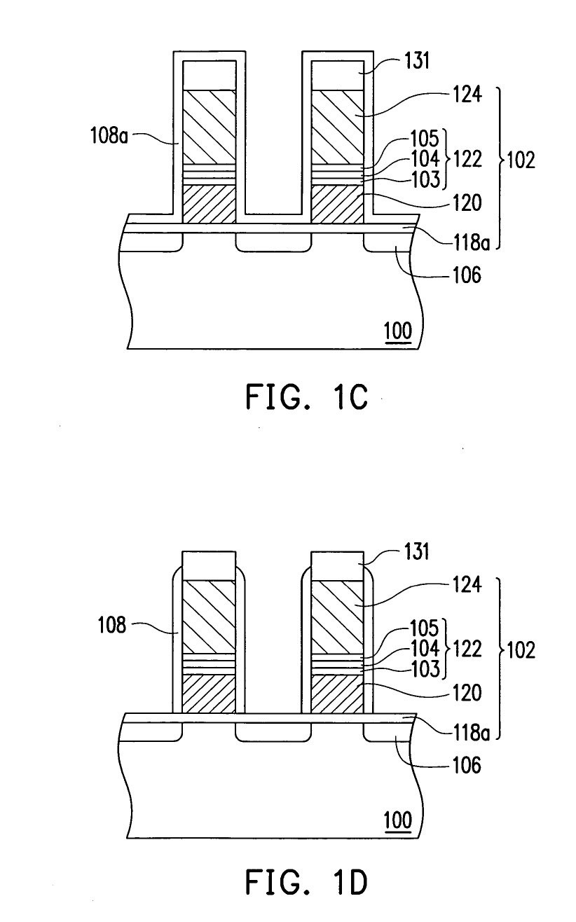

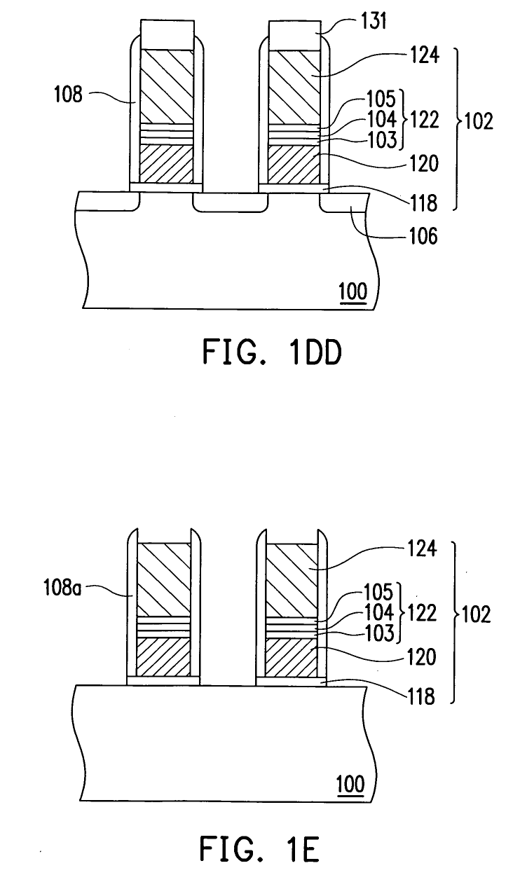

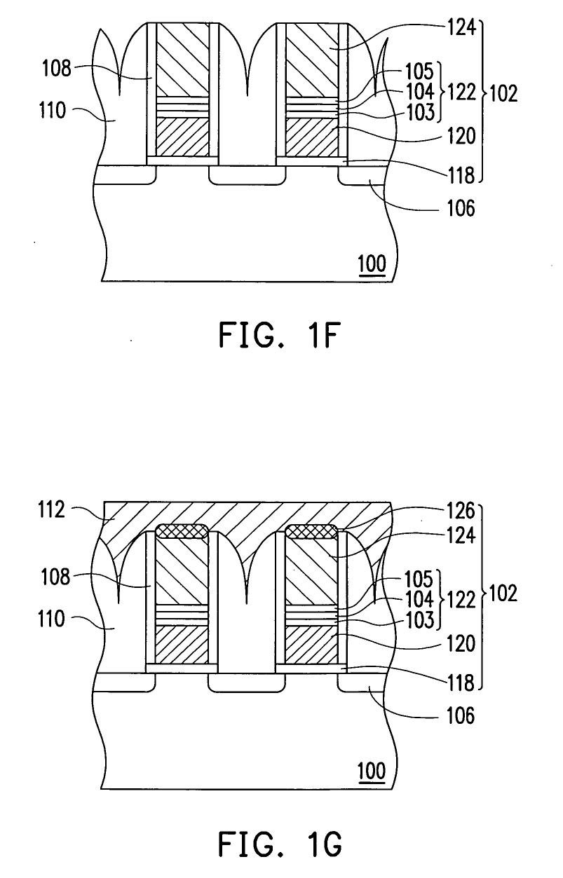

FIGS. 1A through 1G are cross-sectional views showing a method for manufacturing a non-volatile memory cell according to a preferred embodiment of the invention.

As shown in FIG. 1A, a substrate 100 is provided. A stacked gate structure 102 is formed on the substrate 100. The method for forming the stacked gate structure 102 comprises steps of forming a tunnel dielectric material layer 118a, a charge storage material layer 120a, a dielectric material layer 122a, a conductive material layer 124a and a cap material layer 131a over the substrate 100 sequentially. The tunnel dielectric material layer 118a can be, for example but not limited to, made of silicon oxide. The charge storage material layer 120a can be, for example but not limited to, made of doped polysilicon. The dielectric material layer 122a can be, for example but not limited to, a complex layer composed of a silicon oxide layer 103a, a silicon nitride layer 104a and a silicon oxide layer 105a. The conductive material layer 124a can be, for example but not limited to, made of doped polysilicon. The cap material layer 131a can be, for example but not limited to, made of silicon nitride or silicon oxide. Then, a patterned photoresist layer 133 is formed over the cap material layer 131a.

As shown in FIG. 1B, the cap material layer 131a is etched by using the patterned photoresist layer 133 as a mask to form a patterned cap layer 131. Thereafter, the patterned photoresist layer 133 is removed and the conductive material layer 124a, the dielectric material layer 122a, the charge storage material layer 120a and the tunnel dielectric material layer 118a are etched by using the cap layer 131 as a mask to form a conductive layer 124, a dielectric layer 122, a charge storage layer 120 and a dielectric layer 118 respectively. The method for etching the dielectric material layer 122a, the charge storage material layer 120a and the tunnel dielectric material layer 118a includes a dry etching process. Further, the conductive layer 124, the dielectric layer 122, the charge storage layer 120 and the dielectric layer 118 together form the stacked gate structure 102. In one embodiment, the non-volatile memory cell can be, for example but not limited to, a flash memory cell. The conductive layer 124 can be used as a control gate. The dielectric layer 122 can be a gate dielectric layer. The charge storage layer 120 can be a floating gate and the tunnel dielectric layer 118 can be a tunnel oxide layer. Since, during the stacked gate structure is defined, the cap material layer 131a is patterned by using the photoresist layer 133 as a mask and then the material layers in the stack gate structure are patterned by using the cap layer 131 as a mask, the thickness of the patterned photoresist layer is relatively small.

As shown in FIG. 1C, doped regions 106 are formed in the substrate 100 adjacent to the both sides of the stacked gate structure 102. The method for forming the doped regions 106 includes an ion implantation process. Furthermore, for a single memory cell (single stacked gate structure 102), the doped regions 106 can be taken as source/drain regions. For more than one memory cell, the doped regions 106 are taken as the buried bit line for connecting the memory cells to each other. Then, a conformal protective layer 108a is formed over the substrate 100. The material of the protective layer 108a is different from that of the cap layer 131. The thickness of the protective layer 108a is about 50˜200 angstrom. The method for forming the protective layer 108a can be, for example but not limited to, a chemical vapor deposition (CVD). When the cap layer 131 is made of silicon nitride, the protective layer 108a is made of silicon oxide. When the cap layer 131 is made of silicon oxide, the protective layer 108a is made of silicon nitride.

As shown in FIG. 1D and FIG. 1DD, a portion of the protective layer 108a is removed to form a protective layer 108 on the sidewall of the stacked gate structure 102 and expose the cap layer 131. The method for removing the portion of the protective layer 108a can be, for example but not limited to, a dry etching process. In one embodiment, when the cap layer 131 is made of silicon oxide and the protective layer 108 is made of silicon nitride, the recipe of the dry etching process for removing the portion of the protective layer 108a comprises the pressure of about 150 mTorr˜250 mTorr, the power of about 200 W˜400 W, the bias power of about 50 W˜150 W, the flow rate of CHF₃ of about 40 sccm˜60 sccm and the oxygen flow rate of about 200 sccm˜400 sccm. Preferably, the recipe of the dry etching process comprises the pressure of about 220 mTorr, the power of about 300 W, the bias power of about 100 W, the flow rate of CHF₃ of about 50 sccm and the oxygen flow rate of about 300 sccm. Since the material of the tunnel dielectric material layer 118a is different from that of the protective layer 108a and the selective ratio of the protective layer 108a to the tunnel dielectric material layer 118a is high in the etching process, the tunnel dielectric material layer 118a remains after the dry etching process is performed. The result is shown in FIG. 1D.

In another embodiment, when the material of the cap layer 131 is silicon nitride and the material of the protective layer 108a is silicon oxide, the recipe of the dry etching process for removing the portion of the protective layer 108a comprises the pressure of about 50 mTorr˜60 mTorr, the power of about 400 W˜600 W, the bias power of about 100 W˜300 W, the flow rate of C₄F₆ of about 5 sccm˜15 sccm and the oxygen flow rate of about 5 sccm˜15 sccm. Preferably, the recipe of the dry etching process comprises the pressure of about 55 mTorr, the power of about 500 W, the bias power of about 100 W, the flow rate of C₄F₆ of about 11 sccm and the oxygen flow rate of about 10 sccm. Since the material of the tunnel dielectric material layer 118a is as same as that of the protective layer 108a, a portion of the tunnel dielectric material layer 118a is removed to expose the doped regions 106 after the dry etching process is performed. The result is shown in FIG. 1DD.

Then, as shown in FIG. 1E, an etching process is performed by using an etching solvent with high etching selectivity ratio of the cap layer 131 to the protective layer 108 to remove the cap layer 131. The etching process can be a wet etching process. When the cap layer 131 is made of silicon nitride, the cap layer 131 can be removed by using hot phosphoric acid. When the cap layer 131 is made of silicon oxide, the cap layer 131 can be removed by using hydrofluoric acid and a portion of the tunnel dielectric material layer 118a which is made of the silicon oxide as well is also removed to expose the doped regions 106. Therefore, no matter the cap layer 131 is made of silicon oxide or silicon nitride, the structure of the memory cell after the etching process is shown FIG. 1E. In the etching process, since the etching rates of the cap layer 131 and the protective layer 108 are different from each other, the protective layer 108 remains on the sidewall of the stacked gate structure 102 to protect the dielectric layer 122 while the cap layer 131 is removed.

As shown in FIG. 1F, a spacer 110 is formed on the protective layer 108 over the sidewall of the stacked gate structure 102 to cover the doped regions 106. The material of the spacer 110 can be, for example but not limited to, silicon nitride or other proper insulating material. Moreover, the method for forming the spacer 110 comprises steps of forming a space material layer (not shown) over the substrate 100 and then performing an anisotropic etching process on the space material layer until the spacer 110 is formed.

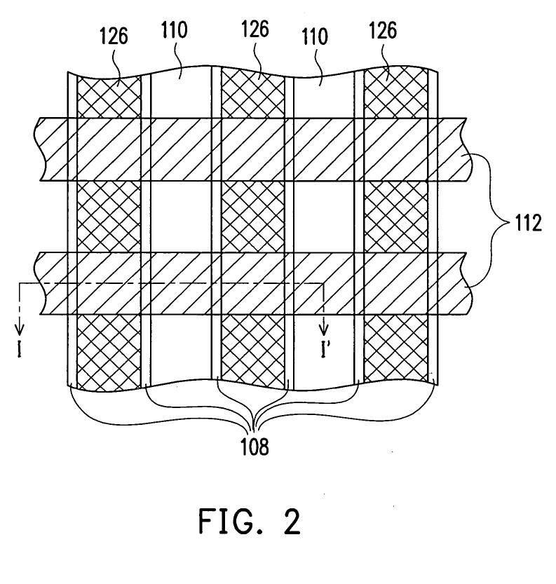

As shown in FIG. 1G, a self-aligned metal silylation process is performed to form a metal silicide layer 126 over the stacked gate structure 102. The self-aligned metal silylation process comprises steps of depositing a metal layer (not shown) over the substrate 100, performing a thermal process to form the metal silicide layer 126 and then removing the unreacted metal layer. Then, several word lines 112 are formed over the substrate 100 to electrically connect to the stacked gate structure 102. The top view of FIG. 1E is shown in FIG. 2. FIG. 1G is the cross-sectional view along a line I-I′ on FIG. 2. The material of the word lines 112 can be, for example but not limited to, polysilicon. The method for forming the word lines 112 can be, for example. but not limited to, chemical vapor deposition (CVD). Thereafter, the successive processes are performed. The successive processes are well known in the art and are not described herein.

In the present invention, since the protective layer is located on the sidewall of the stacked gate structure of the memory cell, the dielectric layers in the stacked gate structure can be prevented from being damaged during the etching process for removing the cap layer. Therefore, the electrical performance and the yield of the memory cell formed according to the present invention are better.

As shown in FIG. 1G and FIG. 2, the non-volatile memory of the present invention comprises the substrate 100, the stacked gate structure 102, the doped region 106, the protective layer 108, the spacer 110 and the word lines 112.

The substrate 100 can be, for example but not limited to, a silicon substrate. The stacked gate structure 102 is located on the substrate 100 and composed of, from the bottom to the top of the stacked gate structure 102, the dielectric layer 118, the charge storage layer 120, the dielectric layer 122, the conductive layer 124 and the metal silicide layer 126. The dielectric layer 118 can be, for example but not limited to, made of silicon oxide. The charge storage layer 120 can be, for example but not limited to, formed from doped polysilicon. The dielectric layer 122 can be a complex layer composed of, from the bottom to the top of the complex layer, the silicon oxide layer 103, the silicon nitride layer 104 and the silicon oxide layer 105. The conductive layer 124 can be, for example but not limited to, made of doped polysilicon. The metal silicide layer 126 can be, for example but not limited to, made of tungsten silicide or cobalt silicide.

Moreover, the doped regions 106 are located in the substrate 100 adjacent to the both sides of the stacked gate structure 102. The doped regions 106, for a singe memory cell (a single stacked gate structure 102), can be taken as the source/drain regions. For several memory cells, the doped regions 106 can be taken as the buried bit line for connecting the memory cells to each other.

Moreover, the protective layer 108 is located on the sidewall of the stacked gate structure 102. The thickness of the protective layer 108 is about 50˜200 angstrom. The material of the protective layer 108 can be, for example but not limited to, silicon oxide or silicon nitride. Further, the spacer 110 is located on the protective layer 108 over the sidewall of the stacked gate structure 102. The spacer 110 can be, for example but not limited to, made of silicon oxide.

Additionally, several word lines 112 are located over the substrate 100 and parallel to each other. The word line 112 are electrically connected to the stacked gate structure 102 through the metal silicide layer 126. The material of the word lines 112 can be, for example but not limited to, copper or polysilicon.

Since the photoresist layer is used as a mask for patterning the cap layer and then the patterned cap layer is used as a hard mask for patterning the material layers in the stacked gate structure, the thickness of the photoresist layer can be relatively small. Furthermore, because the protective layer is located on the sidewall of the stacked gate structure, the material layers in the stacked gate structure can be prevented from being damaged in the etching process. Therefore, the electrical performance of the memory cells is uniform.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A method for manufacturing a non-volatile memory, comprising:
providing a stacked gate structure over a substrate, wherein the stacked gate structure is composed of, from the bottom to the top of the stacked gate structure, a first dielectric layer, a charge storage layer, a second dielectric layer, a conductive layer and a cap layer;
forming a source/drain region in the substrate;
forming a protective layer on the sidewall of the stacked gate structure; and
performing an etching process to remove the cap layer, wherein, in the etching process, the cap layer and the protective layer have different etching rate.

2. The method of claim 1, wherein the thickness of the protective layer is about 50˜200 angstrom.

3. The method of claim 1, wherein the method for forming the protective layer comprises:
forming a conformal protective layer over the substrate; and
removing a portion of the conformal protective layer to form the protective layer on the sidewall of the stacked gate structure.

4. The method of claim 3, wherein the material of the protective layer is different from that of the cap layer.

5. The method of claim 4, wherein the cap layer is made of silicon oxide and the protective layer is made of silicon nitride.

6. The method of claim 5, wherein the method for removing the portion of the conformal protective layer includes a dry etching process and a recipe of the dry etching process comprises:
flow rate of CHF₃: 40 sccm˜60 sccm; and
oxygen flow rate: 200 sccm˜400 sccm.

7. The method of claim 4, wherein the material of the protective layer is silicon oxide and the material of the cap layer is silicon nitride.

8. The method of claim 7, wherein the method for removing the portion of the conformal protective layer includes a dry etching process and a recipe of the dry etching process comprises:
flow rate of C₄F₆: 5 sccm˜15 sccm; and
oxygen flow rate: 5 sccm˜15 sccm.

9. The method of claim 1, wherein the method for forming the stacked gate structure comprises:
forming a first dielectric material layer, a charge storage material layer, a second dielectric material layer, a conductive material layer and a cap material layer sequentially;
forming a patterned photoresist layer over the cap material layer;
etching the cap material layer by using the patterned photoresist layer as a mask to form the cap layer;
removing the patterned photoresist layer; and
etching the conductive material layer, the second dielectric material layer, the charge storage material layer and the first dielectric material layer by using the cap layer as a mask to form the stacked gate structure.

10. The method of claim 1, wherein the etching process includes a wet etching process.

11. The method of claim 1, after the cap layer is removed, further comprising a step of performing a self-aligned metal silylation process to from a metal silicide layer over the stacked gate structure.

12. The method of claim 11, after the cap layer is removed and before the self-aligned metal silylation process is performed, further comprising a step of forming a spacer on the protective layer over the sidewall of the stacked gate structure.

13. A non-volatile memory cell, comprising:
a substrate;
a stacked gate structure located on the substrate, wherein the stacked gate structure is composed of, from the bottom to the top of the stacked gate structure, a first dielectric layer, a charge storage layer, a second dielectric layer, a conductive layer and a cap layer;
a protective layer located on the sidewall of the stacked gate structure; and
a plurality of doped regions located in the substrate adjacent to both sides of the stacked gate structure.

14. The non-volatile memory cell of claim 13, the thickness of the protective layer is about 50˜200 angstrom.

15. The non-volatile memory cell of claim 13, the material of the protective layer is silicon oxide.

16. The non-volatile memory cell of claim 13, the material of the cap layer is silicon nitride.

17. The non-volatile memory cell of claim 13 further comprising a metal silicide layer located on the stacked gate structure.

18. The non-volatile memory cell of claim 17 further comprising a spacer located on the protective layer over the sidewall of the stacked gate structure.
